(19) United States
(12) Patent Application Publication
(10) Pub. No.: US 2024/0164220 A1
(43) Pub. Date: May 16, 2024

(54) MAGNETORESISTIVE RANDOM ACCESS DEVICE

(71) Applicant: SAMSUNG ELECTRONICS CO., LTD., Suwon-si (KR)

(72) Inventors: Hyungjong JEONG, Suwon-si (KR); Seungpil KO, Suwon-si (KR); Byoungjae BAE, Suwon-si (KR); Manjin EOM, Suwon-si (KR); Gawon LEE, Suwon-si (KR); Kuhoon CHUNG, Suwon-si (KR)

(21) Appl. No.: 18/384,404

(22) Filed: Oct. 27, 2023

(30) Foreign Application Priority Data
Nov. 15, 2022 (KR) 10-2022-0152507

(51) Int. Cl. H10N 50/80; G11C 11/16; H10B 61/00; H10N 50/10

(52) U.S. Cl. CPC H10N 50/80; G11C 11/161; H10B 61/20; H10N 50/10; H10N 50/01

(57) ABSTRACT

A magnetoresistive random access memory device includes a substrate; conductive patterns on the substrate; an insulating interlayer covering the conductive patterns; a lower electrode contact passing through the insulating interlayer, the lower electrode contact contacting the conductive pattern; a lower electrode on the lower electrode contact, the lower electrode including a rounded sidewall; and a memory structure on the lower electrode, the memory structure including a stacked MTJ structure and upper electrode, wherein a width of the lower electrode increases from a lower portion to an upper portion, the memory structure has a sidewall slope such that a width of the memory structure increases from an upper portion to a lower portion, and at least a portion of a sidewall of the lower electrode is covered by the first insulating interlayer.

### CROSS-REFERENCE TO RELATED APPLICATION

This application claims priority under 35 USC § 119 to Korean Patent Application No. 10-2022-0152507, filed on Nov. 15, 2022, in the Korean Intellectual Property Office (KIPO), the contents of which are incorporated by reference herein in their entirety.

### BACKGROUND

### 1. Field

Embodiments relate to a magnetoresistive random access memory (MRAM) device.

### 2. Description of the Related Art

Each cell in a magnetoresistive memory device may include a cell structure in which a lower electrode having a small upper surface, an MTJ structure, and an upper electrode are sequentially stacked. In manufacturing for the magnetoresistive memory device, a patterning process for forming the cell structure may be performed.

### SUMMARY

The embodiments may be realized by providing a magnetoresistive random access memory device including a substrate; conductive patterns on the substrate; an insulating interlayer covering the conductive patterns; a lower electrode contact passing through the insulating interlayer, the lower electrode contact contacting the conductive patterns; a lower electrode on the lower electrode contact, the lower electrode including a rounded sidewall; and a memory structure on the lower electrode, the memory structure including a stacked MTJ structure and upper electrode, wherein a width of the lower electrode increases from a lower portion to an upper portion, the memory structure has a sidewall slope such that a width of the memory structure increases from an upper portion to a lower portion, and at least a portion of a sidewall of the lower electrode is covered by the first insulating interlayer.

The embodiments may be realized by providing a magnetoresistive random access memory device a substrate; a lower electrode contact on the substrate; a lower electrode contacting an upper surface of the lower electrode contact; and a memory structure contacting an entire upper surface of the lower electrode, the memory structure including a stacked MTJ structure and upper electrode, wherein the lower electrode has a rounded sidewall and a width of the lower electrode increases from a lower portion to an upper portion.

The embodiments may be realized by providing a magnetoresistive random access memory device including a substrate; a lower structure on the substrate; an insulating interlayer covering the lower structure; a lower electrode contact passing through the insulating interlayer and contacting a portion of the lower structure, the lower electrode contact having an upper surface lower than an uppermost surface of the insulating interlayer; a lower electrode on the lower electrode contact, the lower electrode having a width increasing from a lower portion to an upper portion, and the lower electrode including a rounded sidewall; and a memory structure in which an MTJ structure and an upper electrode are stacked on the lower electrode, wherein a bottom surface of the lower electrode has an area that is the same as or less than an area of an upper surface of the lower electrode contact.

### BRIEF DESCRIPTION OF THE DRAWINGS

Features will be apparent to those of skill in the art by describing in detail exemplary embodiments with reference to the attached drawings in which:

FIGS. 1 to 12 are cross-sectional views of stages in a method of manufacturing a magnetoresistive memory device according to example embodiments.

FIGS. 13 to 16 are cross-sectional views of stages in a method for manufacturing a magnetoresistive memory device according to example embodiments.

FIGS. 17 to 21 are cross-sectional views of stages in a method for manufacturing a magnetoresistive memory device according to example embodiments.

FIG. 22 is a cross-sectional view illustrating a magnetoresistive memory device according to example embodiments.

FIG. 23 is a cross-sectional view illustrating a magnetoresistive memory device according to example embodiments.

FIG. 24 is a cross-sectional view illustrating a magnetoresistive memory device according to example embodiments.

FIGS. 25 to 29 are cross-sectional views of stages in a method for manufacturing a magnetoresistive memory device according to example embodiments.

### DETAILED DESCRIPTION

Hereinafter, preferred embodiments will be described in detail with reference to the accompanying drawings.

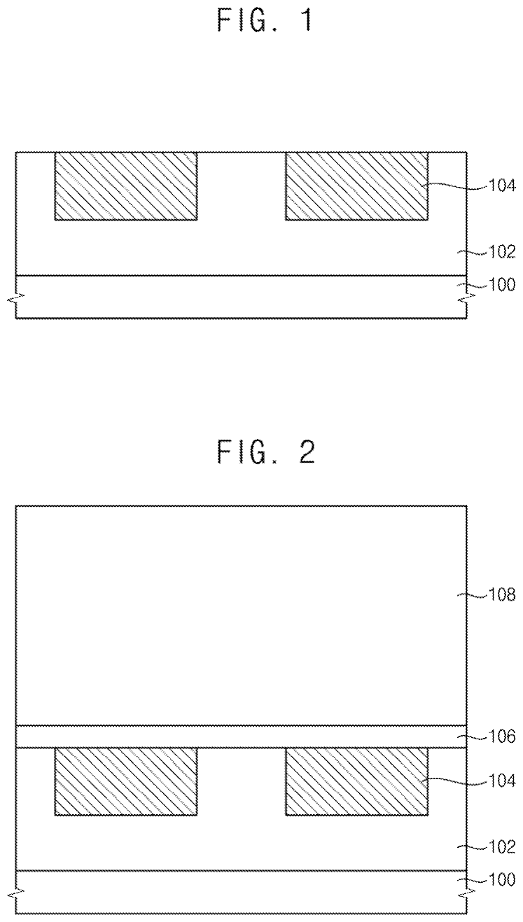

FIGS. 1 to 12 are cross-sectional views of stages in a method for manufacturing a magnetoresistive memory device according to example embodiments.

Referring to FIG. 1, a lower insulating interlayer 102 may be formed on a substrate 100. Conductive patterns 104 may be formed on the lower insulating interlayer 102.

The substrate 100 may include, e.g., silicon, germanium, silicon-germanium, or a group III-V compound such as GaP, GaAs, or GaSb. In an implementation, the substrate 100 may be a silicon-on-insulator (SOI) substrate or a germanium-on-insulator (GOI) substrate. As used herein, the term “or” is not an exclusive term, e.g., “A or B” would include A, B, or A and B.

In an implementation, various elements such as word lines, transistors, diodes, source lines, and wirings may be further formed on the substrate 100.

The lower insulating interlayer 102 may include, e.g., silicon oxide. The lower insulating interlayer 102 may be formed by a chemical vapor deposition (CVD) process, an atomic layer deposition (ALD) process, or a spin coating process.

Upper portions of the lower insulating interlayer 102 may be etched to form openings, and a lower conductive layer may be formed on the lower insulating interlayer 102 to fill the openings. An upper portion of the lower conductive layer may be planarized until an upper surface of the lower insulating interlayer 102 is exposed to form the conductive pattern 104 in each of the openings. The planarization process may include a chemical mechanical polishing (CMP) process.

The conductive patterns 104 may include a metal-containing material, e.g., tungsten, titanium, tantalum, tungsten nitride, titanium nitride, tantalum nitride, or the like. In an implementation, the conductive patterns 104 may include doped polysilicon.

Upper surfaces of the lower insulating interlayer 102 and the conductive pattern 104 may be coplanar with each other, and the upper surfaces of the lower insulating interlayer 102 and the conductive pattern 104 may be substantially flat.

Referring to FIG. 2, an etch stop layer 106 may be formed on the lower insulating interlayer 102 and the conductive pattern 104. A first insulating interlayer 108 may be formed on the etch stop layer 106.

The etch stop layer 106 may include a material having a high etch selectivity with respect to the first insulating interlayer 108. In an implementation, the etch stop layer 106 may include silicon nitride, and the first insulating interlayer 108 may include silicon oxide.

A lower electrode contact and a lower electrode may be formed in the first insulating interlayer 108 in subsequent processes. A maximum thickness of the first insulating interlayer 108 remaining in a finally manufactured magnetoresistive memory device may be equal to a sum of a height of the lower electrode contact and a height of the lower electrode.

An upper portion of the first insulating interlayer 108 may be partially etched during the subsequent processes. Therefore, a deposition thickness of the first insulating interlayer 108 may be greater than a sum of a target height of the lower electrode contact and a target height of the lower electrode.

The first insulating interlayer 108 may be formed by a CVD process, an ALD process, or a spin coating process.

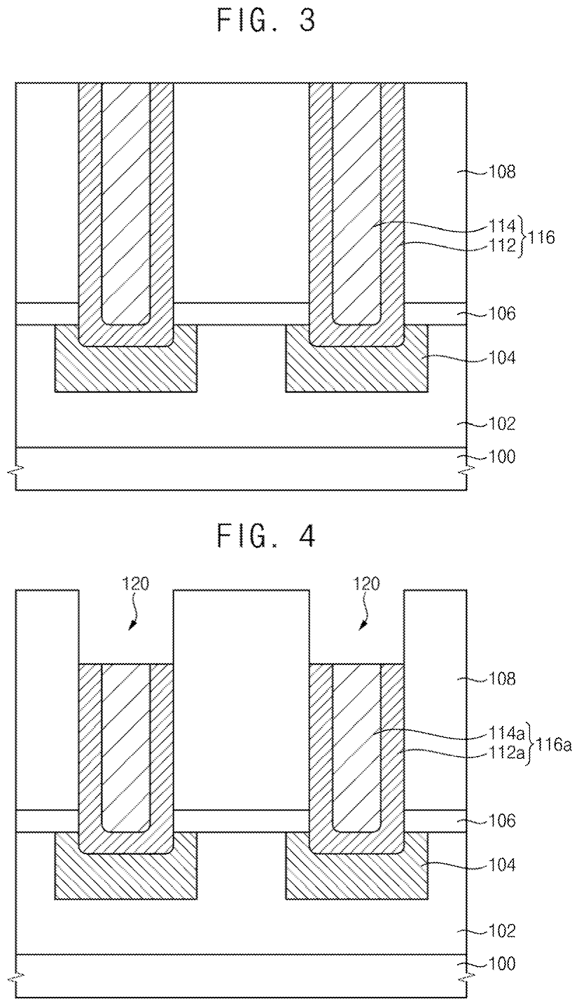

Referring to FIG. 3, a preliminary lower electrode contact 116 contacting the conductive pattern 104 may be formed through the first insulating interlayer 108 and the etch stop layer 106.

In order to form the preliminary lower electrode contact 116, first, the first insulating interlayer 108 and the etch stop layer 106 thereunder may be etched to form a contact hole exposing an upper surface of the conductive pattern 104. In example embodiments, a first barrier metal layer may be conformally formed on a surface of the contact hole and an upper surface of the first insulating interlayer 108, and a first metal layer may be formed on the first barrier metal layer to fill the contact hole. Upper portions of the first barrier metal layer and the first metal layer may be planarized until the upper surface of the first insulating interlayer 108 is exposed to form the preliminary lower electrode contact 116. The preliminary lower electrode contact 116 may include a preliminary first barrier pattern 112 and a preliminary first metal pattern 114. The planarization process may include a CHIP process.

The preliminary first barrier pattern 112 may include, e.g., titanium, tantalum, tungsten nitride, titanium nitride, tantalum nitride, or the like. The preliminary first metal pattern 114 may include, e.g., tungsten, copper, aluminum, or the like. The preliminary first metal pattern 114 may include, e.g., titanium nitride.

In some example embodiments, the preliminary lower electrode contact 116 may include one material, and may not be divided into the preliminary first barrier pattern and the preliminary first metal pattern. For example, the preliminary lower electrode contact 116 may include titanium, titanium nitride, tantalum nitride, tungsten, or the like.

Referring to FIG. 4, an upper portion of the preliminary lower electrode contact 116 may be removed by an etch-back process to form a lower electrode contact 116a. Further, a preliminary first recess 120 may be formed over the lower electrode contact 116a. The etch-back process may include an anisotropic etching process.

An entire upper surface of the lower electrode contact 116a may correspond to a bottom of the preliminary first recess 120. The entire upper surface of the lower electrode contact 116a may be exposed at the bottom of the preliminary first recess 120. The lower electrode contact 116a may not remain on a sidewall of the preliminary first recess 120.

The lower electrode contact 116a may include a first barrier pattern 112a and a first metal pattern 114a. The first barrier pattern 112a may surround a sidewall and a bottom surface of the first metal pattern 114a.

The lower electrode contact 116a may have a height (e.g., as measured in a vertical direction from the substrate 100) that is lower than a height of the preliminary lower electrode contact 116. The etch-back process may be performed so that the lower electrode contact 116a may have a target height.

In some example embodiments, the lower electrode contact 116a may include one material, and may not be divided into the first barrier pattern and the first metal pattern. For example, the lower electrode contact 116a may include titanium, titanium nitride, tantalum nitride, tungsten, or the like.

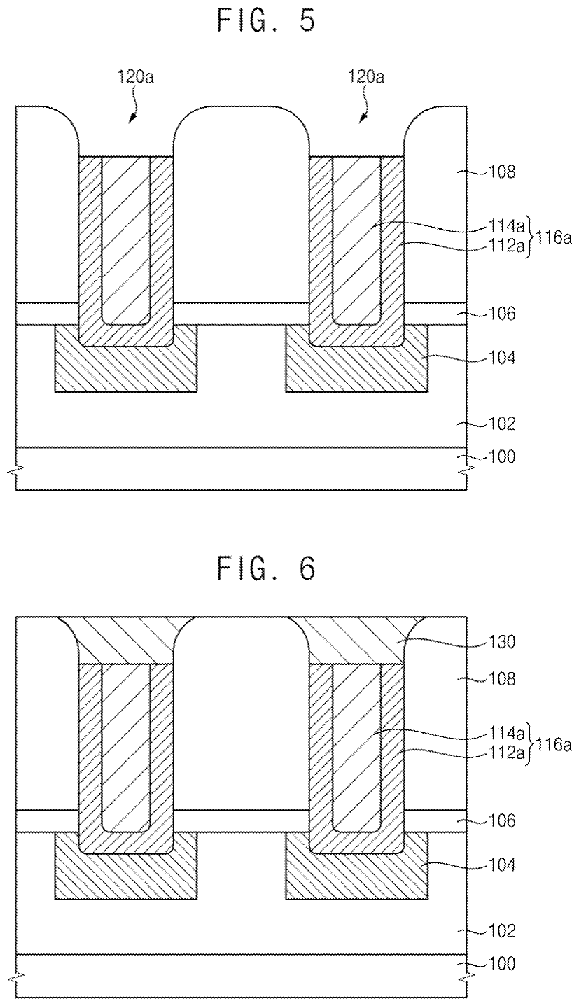

Referring to FIG. 5, the first insulating interlayer 108 corresponding to the upper portion of the preliminary first recess 120 may be partially etched to form a first recess 120a having an upper portion including a rounded corner.

In an implementation, the etching process of the first insulating interlayer 108 may be an isotropic etching process. The isotropic etching may include, e.g., a gas phase dry etching process.

In this case, an upper edge of the preliminary first recess 120 may be etched more than the sidewall of the preliminary first recess 120 due to a three-dimensional effect, so that the upper portion of the preliminary first recess 120 may be rounded. Further, the bottom of the preliminary first recess may hardly be expanded. The height of the first insulating interlayer 108 may be decreased due the etching process. Accordingly, a depth of the first recess 120a may be less than a depth of the preliminary first recess 120.

An upper width of the first recess 120a may be greater than a lower width of the first recess 120a. In an implementation, a width of the first recess 120a may gradually increase from a lower portion toward an upper portion, and the first recess 120a may have a rounded sidewall profile.

Referring to FIG. 6, a lower electrode layer may be formed on the first insulating interlayer 108 to fill the first recess 120a.

The lower electrode layer may be formed by a sputtering process, a physical vapor process (PVD) process, a CVD process, or an ALD process. As an upper width of the first recess 120a is increased, the lower electrode layer may be easily formed in the first recess 120a. Thus, voids or seam defects in the lower electrode layer may be decreased.

The lower electrode layer may be formed of a metal (e.g., non-compounded metal) or a metal nitride. The lower electrode layer may include a metal, e.g., tungsten, titanium, tantalum, or the like, or a metal nitride, e.g., tungsten nitride, titanium nitride, tantalum nitride, or the like.

Thereafter, an upper portion of the lower electrode layer may be planarized until the upper surface of the first insulating interlayer 108 is exposed to form a lower electrode 130. The lower electrode 130 may be formed on the upper surface of the lower electrode contact 116a. The planarization process may include a CMP process.

Upper surfaces of the first insulating interlayer 108 and the lower electrode 130 may be coplanar with each other, and upper surfaces of the first insulating interlayer 108 and the lower electrode 130 may be substantially flat. The lower electrode 130 may be formed in the first recess 120a, and thus the lower electrode 130 may have the same shape as a shape of the first recess 120a. In an implementation, an upper width of the lower electrode 130 may be greater than a lower width of the lower electrode 130. A width of the lower electrode 130 may gradually increase from a lower portion toward an upper portion, and the lower electrode 130 may have a rounded or curved sidewall profile.

A bottom surface of the lower electrode 130 may have an area that is less than an area of an upper surface of the lower electrode 130 (e.g., in a plan view).

In an implementation, the bottom surface of the lower electrode 130 may contact the entire upper surface of the lower electrode contact 116a. In an implementation, the bottom surface of the lower electrode 130 may have the same area as the area of the upper surface of the lower electrode contact 116a.

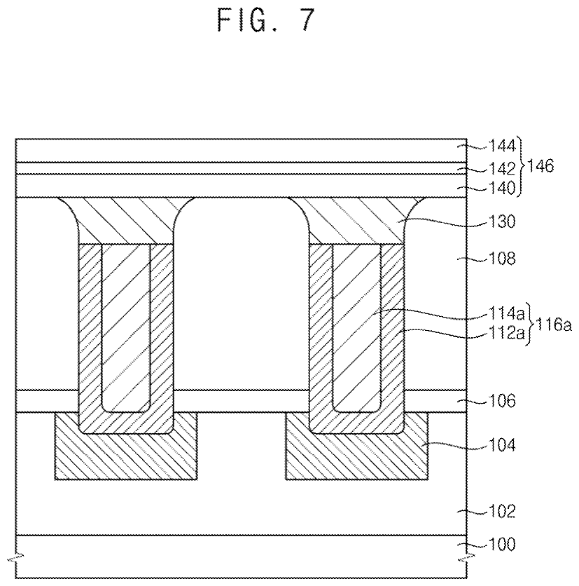

Referring to FIG. 7, an MTJ (magnetic tunnel junction) layer 146 may be formed on the first insulating interlayer 108 and the lower electrode 130. The MTJ layer 146 may include a pinned layer 140, a tunnel barrier layer 142 and a free layer 144 sequentially stacked.

The pinned layer 140 may include a ferromagnetic material, e.g., cobalt, platinum, iron, nickel, or the like. In an implementation, the pinned layer 140 may include an alloy of cobalt and platinum (CoPt), or may have a composite layer structure in which a cobalt layer and a platinum layer are alternately stacked.

The tunnel barrier layer 142 may include, e.g., magnesium oxide or aluminum oxide.

The free layer 144 may include a ferromagnetic material, e.g., cobalt, platinum, iron, nickel, or the like.

In an implementation, at least one of the pinned layer 140, the tunnel barrier layer 142 and the free layer 144 included in the MTJ layer 146 may be formed of a plurality of layers.

In an implementation, the MTJ layer 146 may include the free layer 144, the tunnel barrier layer 142, and the pinned layer 140 sequentially stacked.

The MTJ layer 146 may be formed by, e.g., a sputtering process, a PVD process, a CVD process, or an ALD process.

In an implementation, a blocking layer, an adhesive layer, and a seed layer may be further formed between the lower electrode 130 and the MTJ layer 146 and between the first insulating interlayer 108 and the MTJ layer 146. The blocking layer may include a metal boride, e.g., tantalum boride or titanium boride, a metal boronitride, e.g., tantalum boronitride or titanium boronitride, or a metal compound, e.g., tantalum carbofluoroboride (CFBTa). The adhesive layer may include a metal, e.g., tantalum, titanium, or the like. The seed layer may include a metal, e.g., ruthenium (Ru), rhenium (Re), or the like.

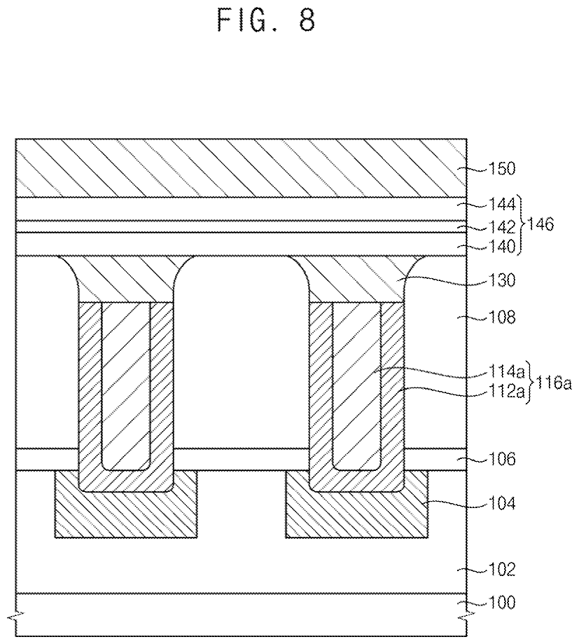

Referring to FIG. 8, an upper electrode layer 150 may be formed on the MTJ layer 146. The upper electrode layer 150 may serve as a hard mask layer for etching the MTJ layer 146.

The upper electrode layer 150 may be formed of a metal or a metal nitride. The upper electrode layer 150 may include a metal, e.g., tungsten, titanium, tantalum, or iron, or a metal nitride, e.g., tungsten nitride, titanium nitride, tantalum nitride, or the like. In an implementation, the upper electrode layer 150 may include tungsten.

The upper electrode layer 150 may be formed by e.g., a sputtering process, a PVD process, a CVD process, or an ALD process.

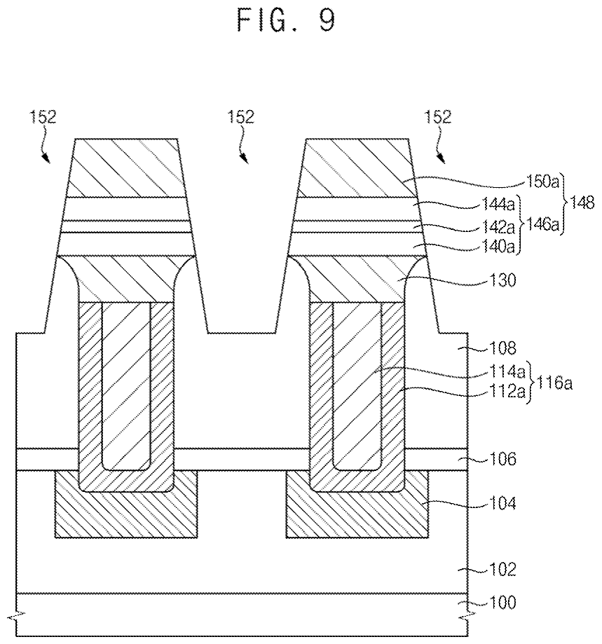

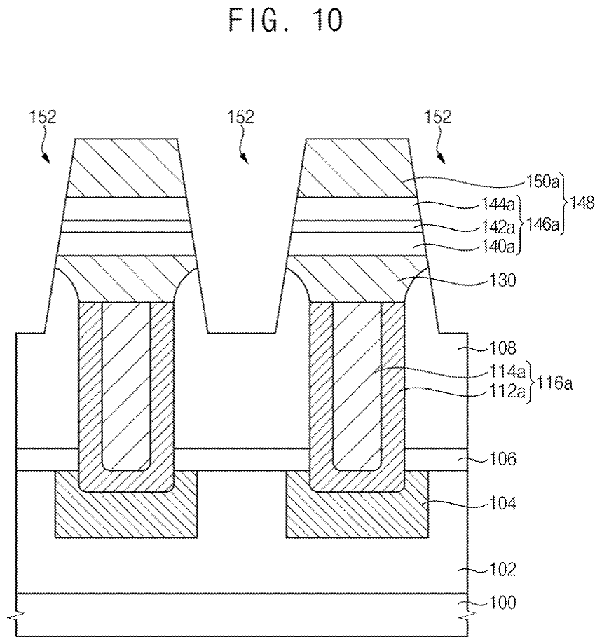

FIGS. 9 and 10, an etching mask pattern may be formed on the upper electrode layer 150, and the upper electrode layer 150 may be etched using the etching mask pattern to form an upper electrode 150a. The etching mask pattern may include a photoresist pattern or an insulation layer pattern.

The MTJ layer 146 and an upper portion of the first insulating interlayer 108 may be sequentially etched using the upper electrode 150a as an etching mask to form memory structures 148. Each of the memory structures 148 may include a MTJ structure 146a and the upper electrode 150a sequentially stacked on the lower electrode 130. During the etching process for forming the memory structure 148, the upper portion of the first insulating interlayer 108 may be etched so that the memory structures 148 may be completely separated from each other. The upper surface of the first insulating interlayer 108 between the memory structures may include a second recess 152.

In an implementation, a blocking pattern, an adhesive pattern, and a seed pattern may be further formed between the lower electrode 130 and the MTJ structure 146a.

The MTJ structure 146a may have a structure in which a pinned layer pattern 140a, a tunnel barrier pattern 142a, and a free layer pattern 144a are stacked.

The etching process may include a dry etching process, e.g., ion beam etching, sputter etching, or radio-frequency (RF) etching. In an implementation, the upper electrode layer 150, the MTJ layer 146 and the first insulating interlayer 108 may be effectively etched by the ion beam etching process.

At least a portion of a sidewall of the lower electrode 130 under the memory structure 148 may be covered by the first insulating interlayer 108. Accordingly, an uppermost surface of the first insulating interlayer 108 may be higher than the bottom surface of the lower electrode 130.

The lower electrode 130 may be already formed before forming the memory structure 148, and thus the lower electrode 130 may not be etched in the etching process for forming the memory structure 148. In an implementation, if an etching position of the MTJ layer 146 were to be out of alignment or shifted due to the deviation of the etching process, an edge portion of the lower electrode 130 could be slightly etched by thin thickness. According to the deviation of the etching process, shapes of the lower electrode 130 and the first insulating interlayer 108 remaining under the memory structure 148 after the etching process may be slightly changed.

As shown in FIG. 9, the MTJ layer 146 and the first insulating interlayer 108 between the lower electrodes 130 may be etched without etching the lower electrode 130. In an implementation, the upper surface of the lower electrode 130 and a lower surface of the MTJ structure 146a may be aligned to or with each other (e.g., may directly face each other). The upper surface of the lower electrode 130 and the lower surface of the MTJ structure 146a may have the same area. In an implementation, a sidewall of the lower electrode 130 under the memory structure 148 may not be exposed, after the etching process. The sidewall of the lower electrode 130 may be covered by the first insulating interlayer 108.

As shown in FIG. 10, the MTJ layer 146 and the first insulating interlayer 108 between the lower electrodes 130, and the upper edge portion of the lower electrode 130 may be etched. In an implementation, the upper surface of the lower electrode 130 and the lower surface of the MTJ structure 146a may be aligned to each other. The upper surface of the lower electrode 130 and the lower surface of the MTJ structure 146a may have the same area. In this case, an upper sidewall of the lower electrode 130 under the memory structure 148 may be exposed, after the etching process.

In an implementation, if a misalignment of an etching portion were to occur in the etching process, an area of the lower surface of the MTJ structure 146a could be greater than that of the upper surface of the lower electrode 130. In this case, after the etching process, a portion of the sidewall of the lower electrode 130 under the memory structure 148 may be exposed, and other portions of the sidewall may not be exposed.

As described above, the lower electrode 130 may be already separately formed before the etching process for forming the memory structure 148, and the lower electrode 130 may not be patterned in the etching process. Therefore, in the etching process for forming the memory structure 148, a thickness of layers to be etched including metals may be decreased. Thus, re-deposition of metals included in etching layers during the etching process may be decreased. Therefore, electrical short or leakage currents caused by the re-deposition of metal on the sidewall of the MTJ structure 146a may be decreased.

If the lower electrode layer were to be patterned by or during etching process, an entire thickness of the lower electrode layer could be etched by the etching process. Therefore, an etching amount of the lower electrode layer could be greatly increased. In the etching process of the lower electrode layer, an electrical short due to the metal re-deposited on the sidewall of the MTJ structure could occur, or a bridge defect between the lower electrodes due to a metal between the lower electrodes could occur.

The memory structure 148 may have a sidewall slope such that a width of the memory structure 148 may be gradually increased from an upper portion (e.g., distal to the substrate 100) toward a lower portion (e.g., proximate to the substrate 100). In a cross sectional view, the memory structure 148 may have a trapezoid shape. In an implementation, in the cross sectional view, a sidewall of the memory structure 148 may have a constant slope.

In an implementation, the lower electrode 130 may have a first sidewall profile such that the width of lower electrode 130 may be gradually increased from the lower portion toward the upper portion. The memory structure 148 on the lower electrode 130 may have a second sidewall profile such that the width of the memory structure 148 may be gradually decreased from the lower portion toward the upper portion. At least a portion of the first sidewall profile may have a rounded shape, and the second sidewall profile may have the constant slope. As the upper width of the lower electrode 130 increases, a contact area between the lower electrode 130 and the MTJ structure 146a may increase. In an implementation, as illustrated in FIG. 10, the lower electrode 130 may have a lower rounded sidewall profile in which the width of the lower electrode 130 gradually increases upwardly from the bottom surface to a maximum width level, and may have an upper flat sidewall profile in which the width of the lower electrode 130 gradually decreases upwardly from the maximum width level to the top surface thereof.

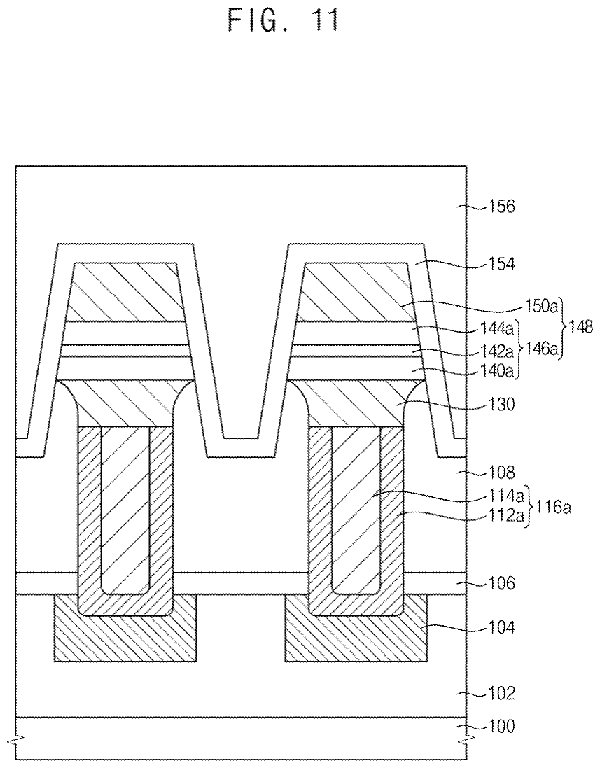

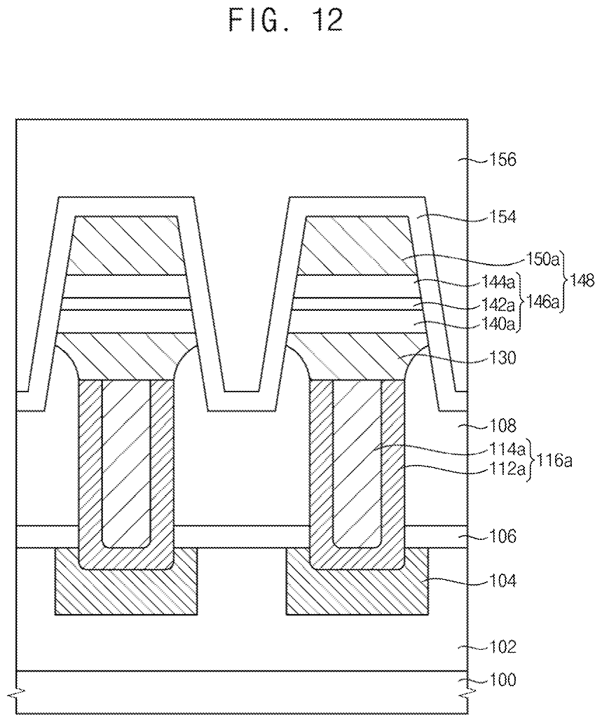

Referring to FIGS. 11 and 12, a protective layer 154 may be formed to cover at least the upper surface of the first insulating interlayer 108 and a surface of the memory structure 148. The protective layer 154 may be conformally formed on at least the upper surface of the first insulating interlayer 108 and a surface of the memory structure 148. In an implementation, the protective layer 154 may include silicon nitride.

In an implementation, the protective layer 154 may not contact at least a portion of the lower electrode 130.

In an implementation, as shown in FIG. 11, the protective layer 154 may cover the upper surface of the first insulating interlayer 108 and the surface of the memory structure 148. The protective layer 154 may not cover (e.g., may not directly contact) the lower electrode 130 under the memory structure 148.

In an implementation, as shown in FIG. 12, the protective layer 154 may cover the upper surface of the first insulating interlayer 108, the surface of the memory structure 148, and an upper sidewall of the lower electrode 130.

A second insulating interlayer 156 may be formed on the protective layer 154. The second insulating interlayer 156 may include silicon oxide.

In an implementation, an upper surface of the second insulating interlayer 156 may be higher than the upper surface of the memory structure 148. In an implementation, a planarization process of the upper surface of the second insulating interlayer 156 may be further performed. In an implementation, the upper surface of the second insulating interlayer 156 may be substantially flat.

A magnetoresistive memory device shown in FIG. 11 or 12 may be manufactured by the above processes. The magnetoresistive memory device may have the following structural characteristics.

Structural features may be described with reference to the magnetoresistive memory device shown in FIG. 11.

Referring to FIG. 11 again, the lower insulating interlayer 102 may be formed on the substrate 100, and the conductive pattern 104 may be formed on the lower insulating interlayer 102. The etch stop layer 106 may be formed on the lower insulating interlayer 102 and the conductive pattern 104. The first insulating interlayer 108 may be formed on the etch stop layer 106.

The lower electrode contact 116a may extend through the first insulating interlayer 108 and the etch stop layer 106, and may contact the conductive pattern 104. The lower electrode contact 116a may include the first barrier pattern 112a and the first metal pattern 114a.

An upper surface of the lower electrode contact 116a may be lower than an uppermost surface of the first insulating interlayer 108.

The lower electrode 130 may contact the upper surface of the lower electrode contact 116a.

In an implementation, a bottom surface of the lower electrode 130 may have an area that is the same as an area of an upper surface of the lower electrode contact 116a. In an implementation, the bottom surface of the lower electrode 130 may contact an entire upper surface of the lower electrode contact 116a.

In an implementation, the bottom surface of the lower electrode 130 may have the area that is less than the area of the upper surface of the lower electrode contact 116a.

An upper width of the lower electrode 130 may be greater than a lower width of the lower electrode 130. The lower electrode 130 may have a rounded sidewall profile such that the width of the lower electrode 130 gradually increases from a lower portion toward an upper portion. The bottom surface of the lower electrode 130 may be smaller than the upper surface of the lower electrode 130.

At least a portion of the sidewall of the lower electrode 130 may be covered by the first insulating interlayer 108. In an implementation, an entire sidewall of the lower electrode 130 may be covered by the first insulating interlayer 108.

In an implementation, an uppermost surface of the first insulating interlayer 108 and the upper surface of the lower electrode 130 may be coplanar with each other (e.g., may be at a save vertical or height level). The bottom surface of the lower electrode 130 may be lower than the uppermost surface of the first insulating interlayer 108.

The memory structure 148 in which an MTJ structure 146a and an upper electrode 150a are stacked may be formed on the lower electrode 130. A second recess may be positioned on the upper surface of the first insulating interlayer 108 between the memory structures 148. The MTJ structure 146a may have a structure in which a pinned layer pattern 140a, a tunnel barrier pattern 142a, and a free layer pattern 144a are stacked.

In an implementation, the upper surface of the lower electrode 130 and the lower surface of the MTJ structure 146a may have the same area. The upper surface of the lower electrode 130 and the lower surface of the MTJ structure 146a may be aligned with each other.

The memory structure 148 may have a sidewall slope such that a width of the memory structure 148 may be gradually increased from an upper portion toward a lower portion. In a cross-sectional view, the memory structure 148 may have a trapezoid shape. In an implementation, in the cross-sectional view, a sidewall of the memory structure 148 may have a constant slope.

In an implementation, the first insulating interlayer 108 between the memory structures 148 may have a recessed shape, so that the upper surface of the first insulating interlayer 108 between the memory structures 148 may be lower than the upper surface of the lower electrode 130.

After forming the memory structure 148, the sidewall of the lower electrode 130 under the memory structure 148 may not be exposed by the second recess 152 (referred to FIG. 9). Accordingly, the sidewall of the lower electrode 130 may be covered by the first insulating interlayer 108.

As described above, the lower electrode 130 may have a first sidewall profile such that the width of the lower electrode 130 may be gradually increased from the lower portion toward the upper portion. The memory structure 148 formed on the lower electrode 130 may have a second sidewall profile such that the width of the memory structure 148 may gradually decrease from the lower portion toward the upper portion.

The protective layer 154 may cover at least the upper surface of the first insulating interlayer 108 and a surface of the memory structure 148. The second insulating interlayer 156 may be formed on the protective layer 154. The protective layer 154 may not contact at least a portion of the lower electrode 130.

In an implementation, the protective layer 154 may cover the upper surface of the first insulating interlayer 108 and the surface of the memory structure 148. The protective layer 154 may not cover the lower electrode 130 formed under the memory structure 148.

Structural features may be described with reference to the magnetoresistive memory device shown in FIG. 12.

The magnetoresistive memory device shown in FIG. 12 may be the same as the magnetoresistive memory device shown in FIG. 11, except for a shape of the lower electrode.

Referring to FIG. 12, a portion of a sidewall of the lower electrode 130 may be covered by the first insulating interlayer 108. An upper sidewall of the lower electrode 130 may be exposed by or at the second recess 152 of the first insulating interlayer 108 between the memory structures 148.

Thus, the protective layer 154 may cover an upper surface of the first insulating interlayer 108, a surface of the memory structure 148, and the upper sidewall of the lower electrode 130.

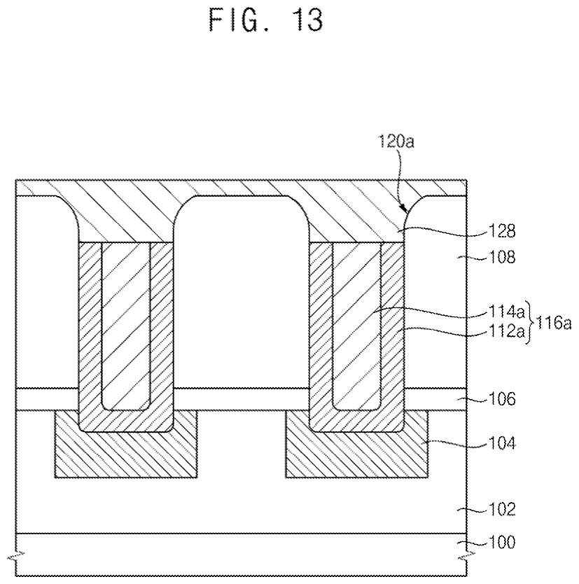

FIGS. 13 to 16 are cross-sectional views of stages in a method for manufacturing a magnetoresistive memory device according to example embodiments.

The method for manufacturing the magnetoresistive memory device described may be the same as those described with reference to FIGS. 1 to 12, except for forming the lower electrode. Therefore, repeated descriptions may be omitted or briefly described.

First, processes described with reference to FIGS. 1 to 5 may be performed.

Referring to FIG. 13, a lower electrode layer 128 may be formed on the first insulating interlayer 108 to fill the first recess 120a.

After that, the lower electrode layer 128 may be planarized until an upper surface of the lower electrode layer 128 is substantially flat. In this case, an upper surface of the first insulating interlayer 108 may not be exposed, after the planarization process.

Accordingly, the lower electrode layer 128 may be formed in the first recess 120a and on the first insulating interlayer 108. The upper surface of the lower electrode layer 128 may be substantially flat. The lower electrode layer 128 on the upper surface of the first insulating interlayer 108 may have a thickness that is less than a thickness of the lower electrode layer 128 formed in the first recess 120a.

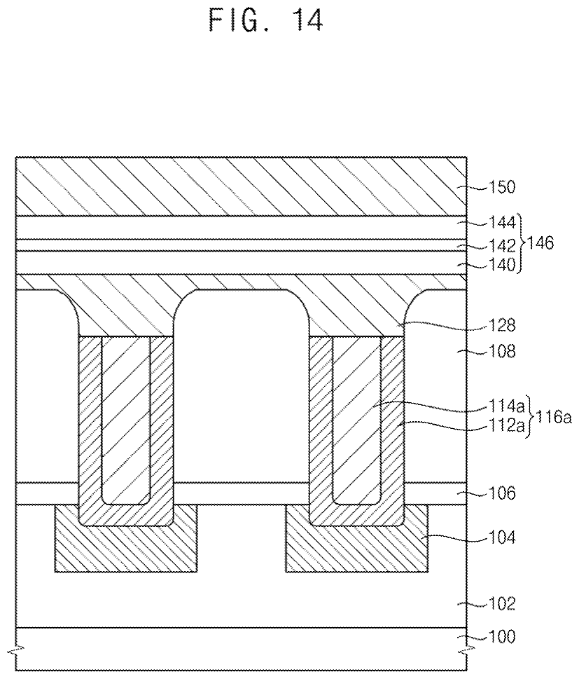

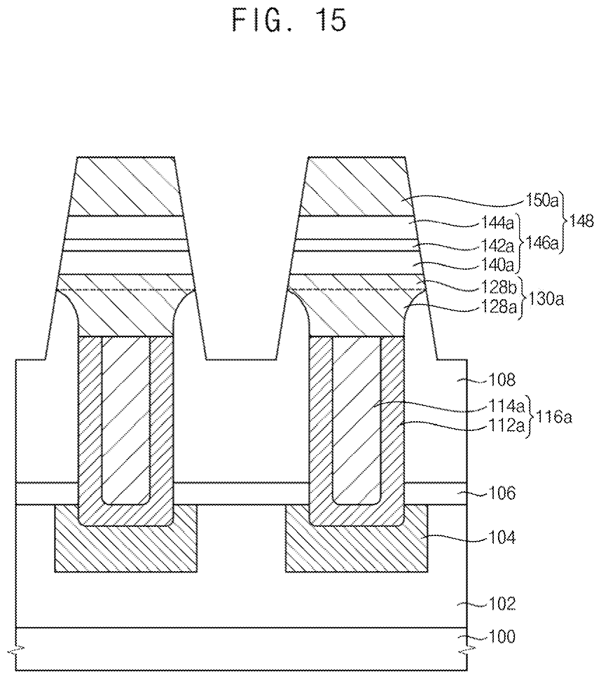

Referring to FIG. 14, the processes described with reference to FIGS. 7 and 8 may be performed on the lower electrode layer 128. Accordingly, the MTJ layer 146 and the upper electrode layer 150 may be formed on the lower electrode layer 128.

Referring to FIG. 15, an etching mask pattern may be formed on the upper electrode layer 150, and the upper electrode layer 150 may be etched using the etching mask pattern to form the upper electrode 150a.

The MTJ layer 146, the lower electrode layer, and an upper portion of the first insulating interlayer 108 may be sequentially etched using the upper electrode 150a as an etching mask to form the lower electrode 130a, the MTJ structure 146a, and the upper electrode 150a. The MTJ structure 146a and the upper electrode 150a sequentially stacked on the lower electrode 130a are referred to the memory structure 148.

In the etching process, the lower electrode layer 128 having the thin thickness on the first insulating interlayer 108 may be etched to form the lower electrode 130a. As such, as an etching amount of the lower electrode layer 128 is decreased, defects generated in the etching process for forming the lower electrode 130a may be decreased.

When the etching process is performed, the memory structure 148 may have a sidewall slope such that a lower width of the memory structure 148 is greater than an upper width of the memory structure 148. In a cross sectional view, the memory structure 148 may have a trapezoid shape.

The lower electrode 130a may include a first portion 128a in the first recess and a second portion 128b protruding from or above the first recess. The first portion 128a of the lower electrode 130a may have a lower sidewall profile such that a width of the first portion 128a of the lower electrode 130 is gradually increased from a lower portion toward an upper portion. The lower sidewall profile may have a rounded shape. The second portion 128b of the lower electrode 130a and the memory structure 148 may have an upper sidewall profile such that a width of the second portion 128b of the lower electrode 130a and the memory structure 148 is gradually decreased from a lower portion to an upper portion. The upper sidewall profile may extend downwardly from a sidewall profile of the memory structure 148 (e.g., may continuously extend from the sidewall of the memory structure 148 such that the combined sidewalls are flat).

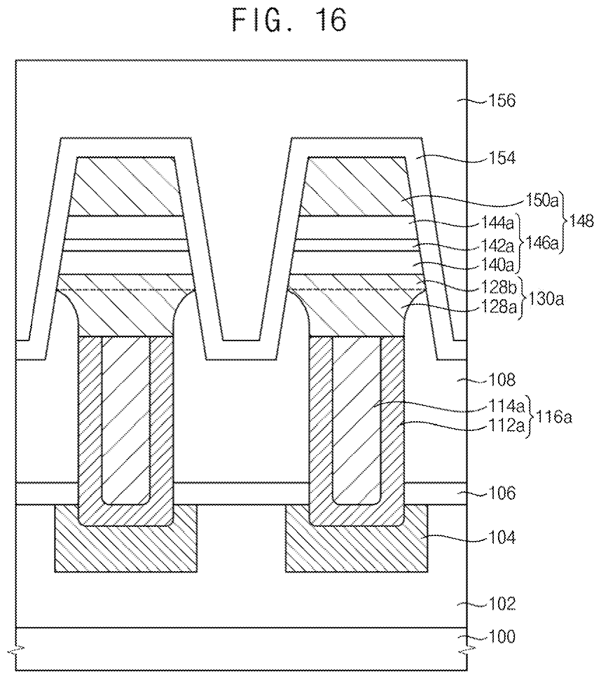

Referring to FIG. 16, the protective layer 154 may be formed to cover the upper surface of the first insulating interlayer 108, the upper sidewall of the lower electrode 130a, and the surface of the memory structure 148. The second insulating interlayer 156 may be formed on the protective layer 154.

By performing the above process, the magnetoresistive memory device may be manufactured. The magnetoresistive memory device formed by the above process may have the following structural characteristics.

Structural features may be described with reference to the magnetoresistive memory device shown in FIG. 16.

Referring to FIG. 16 again, the lower insulating interlayer 102 may be formed on the substrate 100, and the conductive patterns 104 may be formed on the lower insulating interlayer 102. The upper surface of the lower insulating interlayer 102 and the upper surface of the conductive pattern 104 may be coplanar with each other, and may be substantially flat.

The etch stop layer 106 may be formed on the lower insulating interlayer 102 and the conductive pattern 104. The first insulating interlayer 108 may be formed on the etch stop layer 106.

The lower electrode contact 116a may pass through the first insulating interlayer 108 and the etch stop layer 106, and may contact the conductive pattern 104. The upper surface of the lower electrode contact 116a may be lower than an uppermost surface of the first insulating interlayer 108.

The lower electrode 130a may contact the upper surface of the lower electrode contact 116a. The bottom surface of the lower electrode 130a may contact an entire upper surface of the lower electrode contact 116a.

The lower electrode 130a may include the first portion 128a and the second portion 128b. The first portion may be a lower portion of the lower electrode 130a, and may contact the lower electrode contact 116a. The second portion 128b may be on the first portion 128a.

The memory structure 148 in which the MTJ structure 146a and the upper electrode 150a are stacked may be formed on the upper surface of the lower electrode 130a.

In the first portion 128a of the lower electrode 130a, an upper width may be greater than a lower width. The first portion 128a of the lower electrode 130a may have the lower sidewall profile having a rounded shape, and the width of the first portion 128a may gradually increase from a lower portion toward an upper portion. The second portion 128b of the lower electrode 130a and the memory structure 148 may have a second or upper sidewall profile such that a width of the memory structure 148 and the second portion 128b of the lower electrode may be gradually decrease from a lower portion toward an upper portion.

The upper surface of the lower electrode 130a and the lower surface of the MTJ structure 146a may have the same area. The upper surface of the lower electrode 130a and the lower surface of the MTJ structure 146a may be accurately aligned with each other.

At least a sidewall of the first portion 128a of the lower electrode 130a may be covered by the first insulating interlayer 108.

An uppermost surface of the first insulating interlayer 108 may be higher than the bottom surface of the lower electrode 130a.

The protective layer 154 may cover an upper surface of the first insulating interlayer 108, an upper sidewall of the lower electrode 130a, and a surface of the memory structure 148. In an implementation, the protective layer 154 may not be formed on a lower sidewall of the lower electrode 130a. The second insulating interlayer 156 may be formed on the protective layer 154.

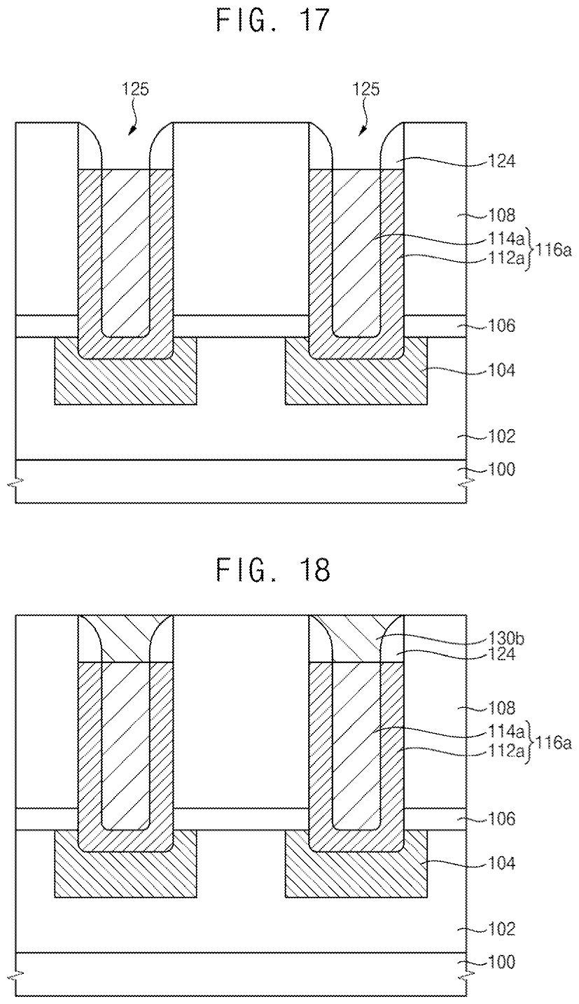

FIGS. 17 to 21 are cross-sectional views of stages in a method for manufacturing a magnetoresistive memory device according to example embodiments.

The method for manufacturing the magnetoresistive memory device may be substantially the same as those described with reference to FIGS. 1 to 12, except for forming the lower electrode. Therefore, repeated descriptions may be omitted or briefly described.

First, processes described with reference to FIGS. 1 to 4 may be performed.

Referring to FIG. 17, an insulation spacer layer may be formed on a surface of the preliminary first recess and an upper surface of the first insulating interlayer 108. The insulation spacer layer may be anisotropically etched to form an insulation spacer 124 on a sidewall of the preliminary first recess.

Accordingly, the preliminary first recess may be transformed as a first recess 125 having a reduced inner width. The insulation spacer 124 may include, e.g., silicon oxide.

The insulation spacer 124 may have a rounded upper portion, so that an upper width of the insulation spacer 124 may be less than a lower width of the insulation spacer 124. Accordingly, an upper width of the first recess 125 may be greater than a lower width of the first recess 125. The first recess 125 may have a sidewall profile so that a width of the first recess may gradually increase from a lower portion toward an upper portion. The first recess 125 may have a rounded sidewall profile.

As the insulation spacer 124 is formed, an entire upper surface of the lower electrode contact 116a may not be exposed at a bottom surface of the first recess 125. In an implementation, only a central portion of the upper surface of the lower electrode contact 116a may be exposed by the bottom surface of the first recess 125.

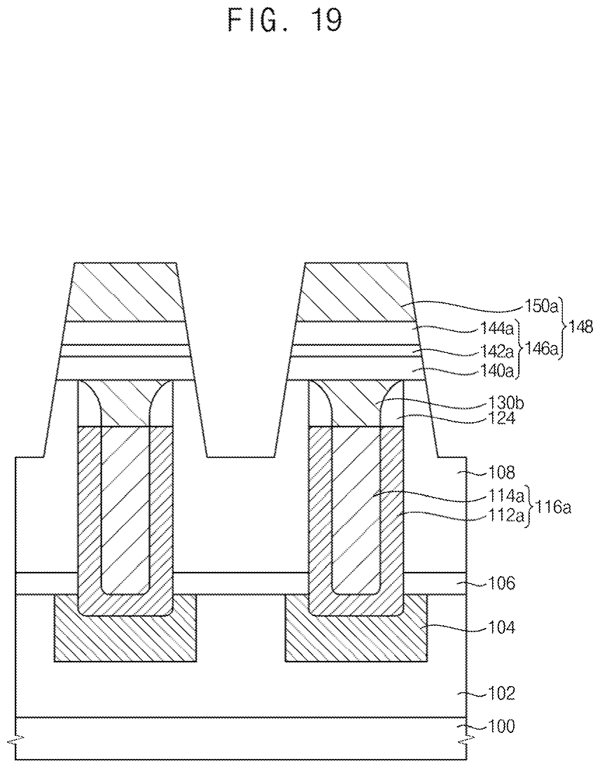

Referring to FIG. 18, the lower electrode layer may be formed on the first insulating interlayer 108 to fill the first recess 125. Thereafter, an upper portion of the lower electrode layer may be planarized until an upper surface of the first insulating interlayer 108 is exposed. The process may be substantially the same as that described with reference to FIG. 6.

An upper width of the lower electrode 130b may be greater than a lower width of the lower electrode 130b. The lower electrode 130b may have a rounded sidewall profile such that a width of the lower electrode 130b may gradually increase from the lower portion toward the upper portion. A bottom surface of the lower electrode 130b may have an area less than an area of an upper surface of the lower electrode 130b.

Also, the bottom surface of the lower electrode 130b may not contact the entire upper surface of the lower electrode contact 116a. In an implementation, the bottom surface of the lower electrode 130b may contact the central portion of the upper surface of the lower electrode contact 116a.

Accordingly, the bottom surface of the lower electrode 130b may have an area that is less than an area of the upper surface of the lower electrode contact 116a.

Referring to FIG. 19, the processes as described with reference to FIGS. 7 to 8 may be performed. Accordingly, the MTJ layer and the upper electrode layer may be formed on the lower electrode 130b and the first insulating interlayer 108.

Thereafter, an etching mask pattern may be formed on the upper electrode layer. The upper electrode layer may be etched using the etching mask pattern to form an upper electrode 150a.

The MTJ layer and the upper portion of the first insulating interlayer 108 thereunder may be etched using the upper electrode 150a to form the memory structure 148. The memory structure 148 may include the MTJ structure 146a and the upper electrode 150a sequentially stacked on the lower electrode 130b.

In the etching process, the MTJ layer and the first insulating interlayer 108 between the lower electrodes 130b may be etched without etching the lower electrodes 130b. In this case, a bottom surface of the MTJ structure 146a may have an area greater than the area of the upper surface of the lower electrode 130b. Accordingly, a portion of the bottom surface of the MTJ structure 146a may contact the first insulating interlayer 108.

The insulation spacer 124 may surround a sidewall of the lower electrode 130b formed below the memory structure 148. An uppermost surface of the first insulating interlayer 108 may be higher than a lower surface of the lower electrode 130b.

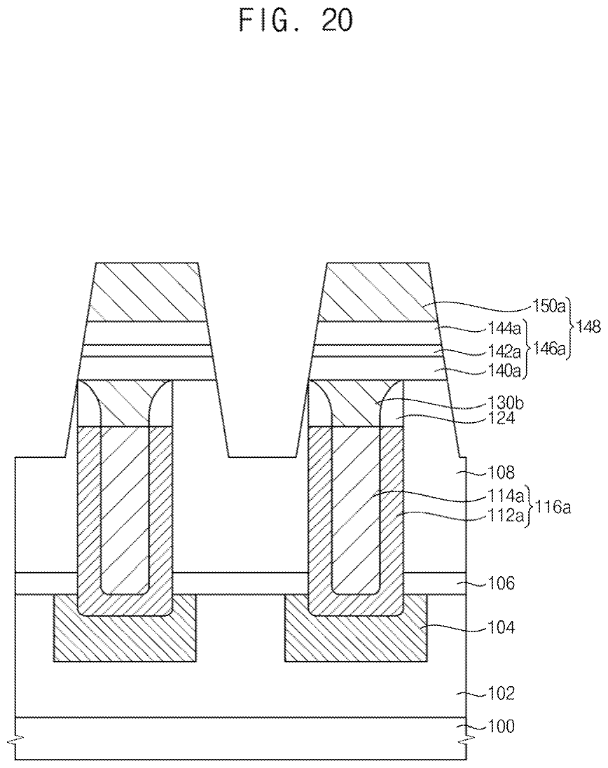

In an implementation, as shown in FIG. 20, a misalignment of an etching portion could occur during the etching process for forming the memory structure.

Even if the misalignment were to occur, the lower electrode 130b may be surrounded by the insulation spacer 124. Thus, the lower electrode 130b may not be exposed during the etching process. Accordingly, defects due to etching of the lower electrode 130b may be decreased.

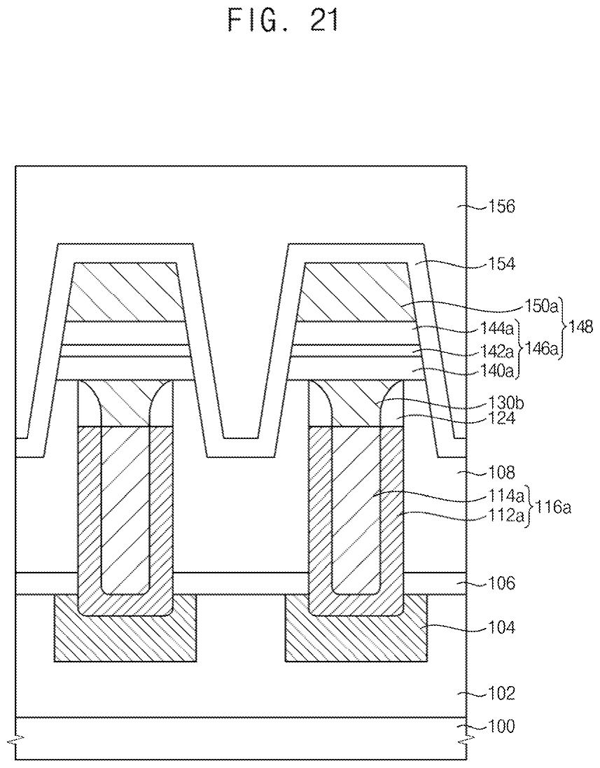

Referring to FIG. 21, the protective layer 154 may be formed to cover an upper surface of the first insulating interlayer 108 and a surface of the memory structure 148. The protective layer 154 may cover the upper surface of the first insulating interlayer 108 and the surface of the memory structure 148, and may not cover a sidewall of the lower electrode 130b under the memory structure 148. The second insulating interlayer 156 may be formed on the protective layer 154.

Structural features may be described with reference to the magnetoresistive memory device shown in FIG. 21.

The magnetoresistive memory device illustrated in FIG. 21 may be the same as or similar to the magnetoresistive memory device illustrated in FIG. 11, except for the lower electrode. Therefore, repeated descriptions are omitted or briefly described.

Referring to FIG. 21 again, the lower insulating interlayer 102 may be formed on the substrate 100, and the conductive pattern 104 may be formed on an upper surface of the lower insulating interlayer 102. The upper surface of the lower insulating interlayer 102 and an upper surface of the conductive pattern 104 may be coplanar with each other, and may be flat.

The etch stop layer 106 may be formed on the lower insulating interlayer 102 and the conductive pattern 104. The first insulating interlayer 108 may be formed on the etch stop layer 106.

The lower electrode contact 116a may pass through the etch stop layer 106, and may contact the conductive pattern 104.

The lower electrode 130b may contact a portion of an upper surface of the lower electrode contact 116a. In an implementation, a bottom surface of the lower electrode 130b may contact a central portion of the upper surface of the lower electrode contact 116a.

The bottom surface of the lower electrode 130b may have an area less than the upper surface of the lower electrode contact 116a.

An upper width of the lower electrode 130b may be greater than a lower width of the lower electrode 130b. The lower electrode 130b may have a rounded sidewall profile. A width of the lower electrode 130b may increase from a lower portion toward an upper portion. The bottom surface of the lower electrode 130b may have an area less than an upper surface of the lower electrode 130b.

The insulation spacer 124 may surround a sidewall of the lower electrode 130b. An upper width of the insulation spacer 124 may be less than a lower width of the insulation spacer 124, and an upper portion of the insulation spacer 124 may have rounded shape. In the insulation spacer 124, an upper inner sidewall contacting the sidewall of the lower electrode 130b may have a rounded shape. In the insulation spacer 124, an outer sidewall not contacting the sidewall of the lower electrode 130b may have a substantially vertical shape.

An uppermost surface of the first insulating interlayer 108 and the upper surface of the lower electrode 130b may be coplanar with each other. The bottom surface of the lower electrode 130b may be lower than the uppermost surface of the first insulating interlayer 108.

The memory structure 148 including the MTJ structure 146a and the upper electrode 150a may be formed on the upper surface of the lower electrode 130b.

A bottom surface of the MTJ structure 146a may have an area greater than an area of the upper surface of the lower electrode 130b. The MTJ structure 146a may completely cover the upper surface of the lower electrode 130b. A portion of the bottom surface of the MTJ structure 146a may contact the first insulating interlayer 108.

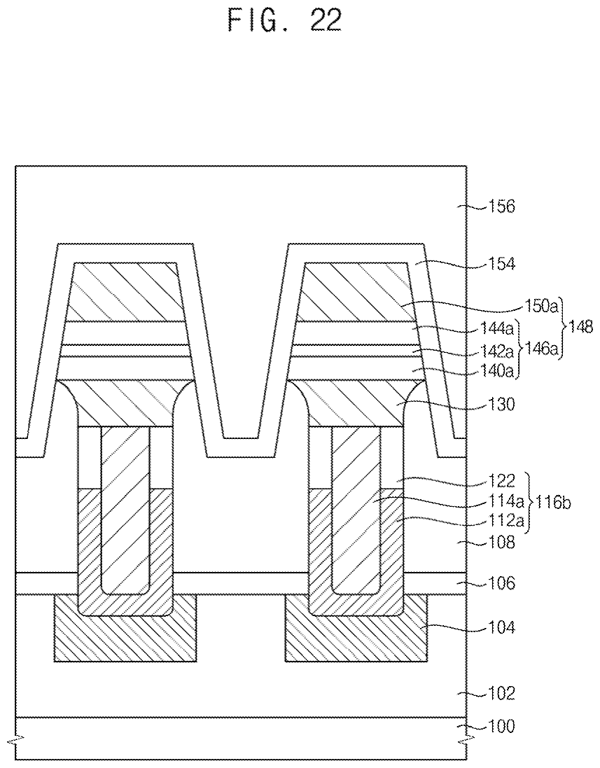

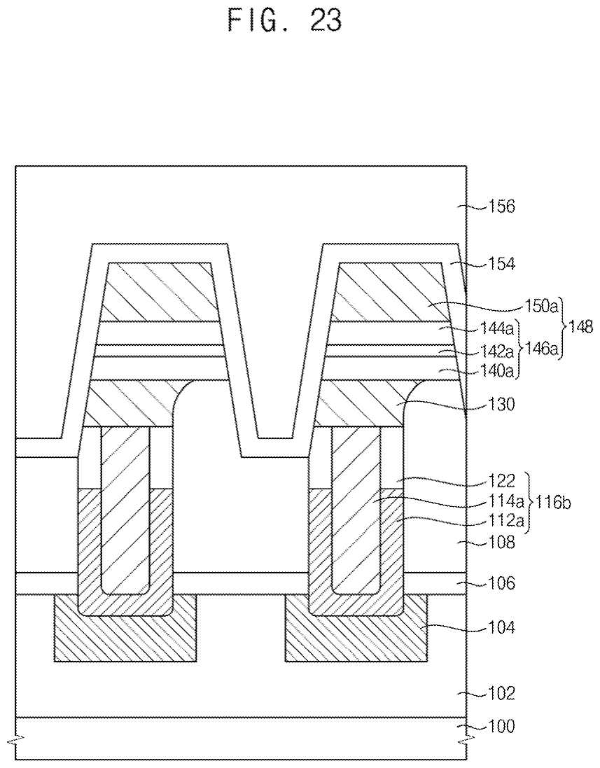

FIG. 22 is a cross-sectional view illustrating a magnetoresistive memory device according to example embodiments. FIG. 23 is a cross-sectional view illustrating a magnetoresistive memory device according to example embodiments.

The magnetoresistive memory device illustrated in FIG. 22 may be the same as or similar to the magnetoresistive memory device illustrated in FIG. 11, except for the lower electrode contact. Therefore, repeated descriptions are omitted or briefly described. FIG. 23 shows the magnetoresistive memory device when the misalignment occurs.

Referring to FIG. 22, a lower electrode contact 116b may pass through the first insulating interlayer 108 and the etch stop layer 106, and may contact the conductive pattern 104.

The lower electrode contact 116b may include a first barrier pattern 112a, an upper insulation spacer 122, and a first metal pattern 114a. The first barrier pattern 112a may surround a lower sidewall and a lower surface of the first metal pattern 114a. The upper insulation spacer 122 may surround an upper sidewall of the first metal pattern 114a. The upper insulation spacer 122 may be on the first barrier pattern 112a. In an implementation, the lower electrode contact 116b may further include the upper insulation spacer 122 surrounding an upper portion of the first metal pattern 114a.

The lower electrode 130, the memory structure 148, and the protective layer 154 may be formed on the lower electrode contact 116b. The lower electrode 130, the memory structure 148, and the protective layer 154 may be substantially the same as those described with reference to FIG. 11, respectively.

A misalignment of an etching portion could occur in an etching process for forming the memory structure 148. In this case, as shown in FIG. 23, one sidewall of the lower electrode 130 could be etched. However, the upper insulation spacer 122 may be formed on the lower electrode contact 116b, and thus the first metal pattern 114a may not be exposed to the outside, after the etching process. Accordingly, defects caused by exposure of the first metal pattern 114a may be decreased.

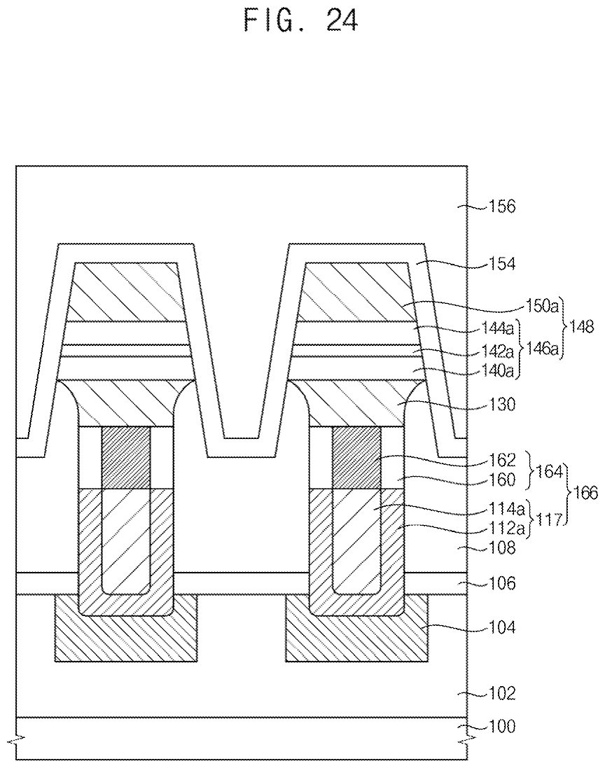

FIG. 24 is a cross-sectional view illustrating a magnetoresistive memory device according to example embodiments.

The magnetoresistive memory device illustrated in FIG. 24 may be the same as or similar to the magnetoresistive memory device illustrated in FIG. 11, except for the lower electrode contact. Therefore, repeated descriptions are omitted or briefly described.

Referring to FIG. 24, a lower electrode contact 166 may pass through the first insulating interlayer 108 and the etch stop layer 106. The lower electrode contact 166 may contact the conductive pattern 104.

The lower electrode contact 166 may include a first electrode contact 117 and a second electrode contact 164.

The first electrode contact 117 may include a first barrier pattern 112a and a first metal pattern 114a. The first barrier pattern 112a may surround a sidewall and a bottom surface of the first metal pattern 114a. The second electrode contact 164 may be stacked on the first electrode contact 117. The second electrode contact 164 may include an upper insulation spacer 160 and a second metal pattern 162.

The upper insulation spacer 160 may surround a sidewall of the second metal pattern 162. The upper insulation spacer 160 may be on the first barrier pattern 112a. The second metal pattern 162 may be on the first metal pattern 114a. The second metal pattern 162 may include a metal having a resistance lower than a resistance of the first metal pattern 114a.

As such, the lower electrode contact 166 including the second electrode contact 164 may have a low resistance.

The lower electrode 130, the memory structure 148, and the protective layer 154 may be formed on the lower electrode contact 166. The lower electrode 130, the memory structure 148 and the protective layer 154 may be substantially the same as those described with reference to FIG. 11, respectively.

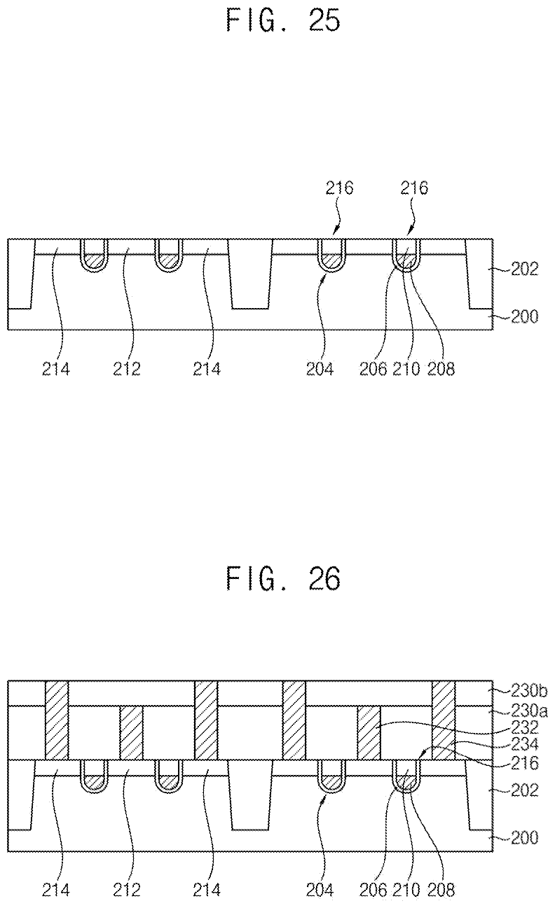

FIGS. 25 to 29 are cross-sectional views of stages in a method for manufacturing a magnetoresistive memory device according to example embodiments.

The method for manufacturing the magnetoresistive memory device may include processes substantially the same as or similar to the processes described with reference to FIGS. 3 to 12, and thus a repeated detailed description thereof may be omitted.

Referring to FIG. 25, an isolation layer 202 may be formed at an upper portion of a substrate 200. The substrate 200 may be divided into an active region and a field region. The isolation layer 202 may be formed by a shallow trench isolation (STI) process. The active region may have an isolated island shape, and a plurality of active regions may be regularly arranged.

Cell transistors 216 may be formed on the substrate 200. In an implementation, two cell transistors 216 may be formed on each of the active regions.

In an implementation, the cell transistors 216 may be buried gate type transistors. In order to form the cell transistors 216, a mask pattern may be formed on the substrate 200. The substrate 200 may be etched using the mask pattern to form trenches 204 extending in a first direction. Two trenches 204 may be formed in each of the active regions, and may be spaced apart from each other. A gate structure including a gate insulation layer pattern 206, a gate electrode 208 and a hard mask pattern 210 may be formed in each of the trenches 204. In an implementation, impurities may be doped into the active regions adjacent to both sides of the gate structure to form a first impurity region 212 and a second impurity region 214, respectively. In an implementation, the first impurity region 212 may serve as a common source region of the two cell transistors 216.

In an implementation, the cell transistors 216 may be the buried gate type transistors. In an implementation, the cell transistors may be planar gate transistors or fin transistors.

Referring to FIG. 26, a first lower insulating interlayer 230a may be formed on the substrate 200 to cover the cell transistors 216. After that, an upper portion of the first lower insulating interlayer 230a may be planarized until an upper surface of the first lower insulating interlayer 230a may be substantially flat. The planarization process may include a CHIP process or etch-back process.

The first lower insulating interlayer 230a may be etched to form first openings exposing surfaces of the first impurity regions 212. In an implementation, each of the first openings may extend (e.g., lengthwise) in the first direction. A first conductive layer may be formed in the first openings, and the first conductive layer may be planarized to form source lines 232 contacting the first impurity regions 212. The source lines 232 may be formed of a metal, e.g., tungsten, titanium, tantalum, or the like, or metal nitride, e.g., tungsten nitride, titanium nitride, tantalum nitride, or the like.

A second lower insulating interlayer 230b may be formed on the first lower insulating interlayer 230a and the source lines 232. The upper surface of the first lower insulating interlayer 230a may be substantially flat, so that an upper surface of the second lower insulating interlayer 230b may be substantially flat. The first and second lower insulating interlayers 230a and 230b may be formed of, e.g., silicon oxide.

Second openings may be formed through the first and second lower insulating interlayers 230a and 230b to expose the second impurity regions 214, respectively. A second conductive layer may be formed in the second openings, and the second conductive layer may be planarized to form lower contact plugs 234 contacting the second impurity regions 214, respectively. The lower contact plugs 234 may be formed of a metal, e.g., tungsten, titanium, tantalum, or the like, or metal nitride, e.g., tungsten nitride, titanium nitride, tantalum nitride, or the like.

In an implementation, the source lines 232 may extend through the first lower insulating interlayer 230a, and the lower contact plugs 234 may extend through the first and second lower insulating interlayers 230a and 230b. Upper surfaces of the lower contact plugs 234 may be higher than upper surfaces of the source lines 232.

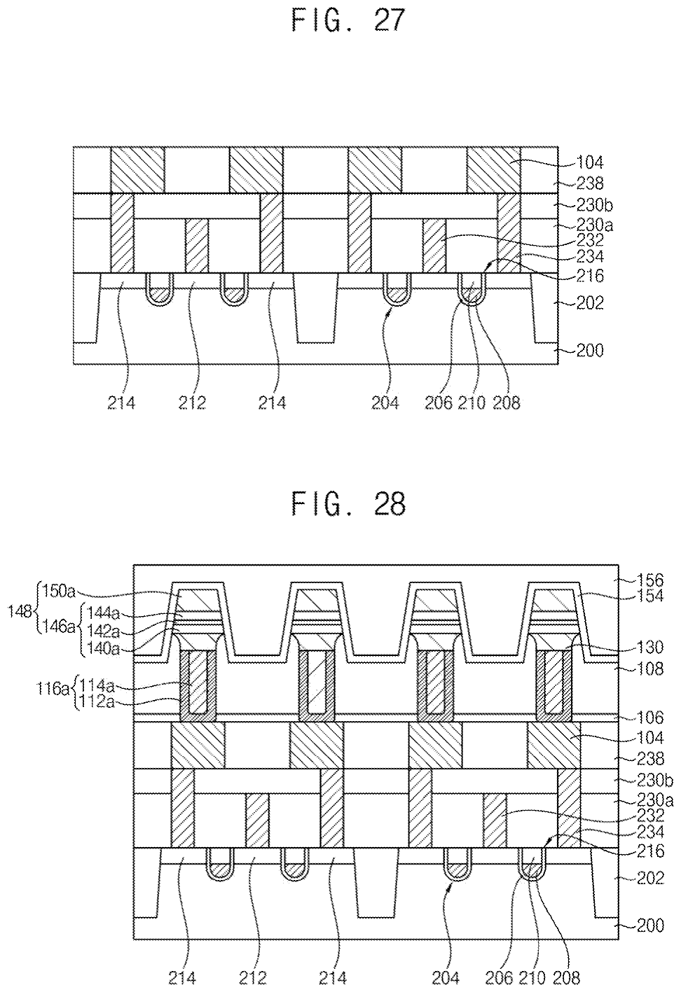

Referring to FIG. 27, conductive patterns 104 contacting the lower contact plugs 234 may be formed on the second lower insulating interlayer 230b and the lower contact plugs 234. In an implementation, an insulation layer pattern 238 may be formed between the conductive patterns 104.

In an implementation, the conductive pattern 104 may be formed by a damascene process. In an implementation, an insulation layer may be formed on the second lower insulating interlayer 230b and the lower contact plugs 234. The insulation layer may be formed of silicon nitride or silicon oxide. The insulation layer may be etched to form an opening exposing an upper surface of the lower contact plug 234. Thereafter, a conductive layer may be formed on the insulation layer to fill the opening. The lower conductive layer may be planarized until an upper surface of the insulation layer may be exposed to form the conductive patterns 104.

In an implementation, the conductive pattern 104 may be formed by an embossed pattern process. In an implementation, a conductive layer may be formed on the second lower insulating interlayer 230b and the lower contact plugs 234. The conductive layer may be patterned to form the conductive patterns 104 contacting the lower contact plugs 234, respectively. Thereafter, an insulation layer may be formed to fill gaps between the conductive patterns 104, and the insulation layer may be planarized to form the insulation layer pattern 238.

Referring to FIG. 28, the processes as described with reference to FIGS. 2 to 11 may be performed on the conductive pattern 104 and the insulation layer pattern 238. Accordingly, a structure the same as that shown in FIG. 11 may be formed on the etch stop layer 106.

In an implementation, the first insulating interlayer 108 may be formed on the etch stop layer 106, and the lower electrode contact 116a may be formed through the first insulating interlayer 108 and the etch stop layer 106. The lower electrode 130 and the memory structure 148 may be formed on the lower electrode contact 116a. The protective layer 154 may be formed to cover the memory structure 48 and the first insulating interlayer 108. The second insulating interlayer 156 may be formed on the protective layer 154.

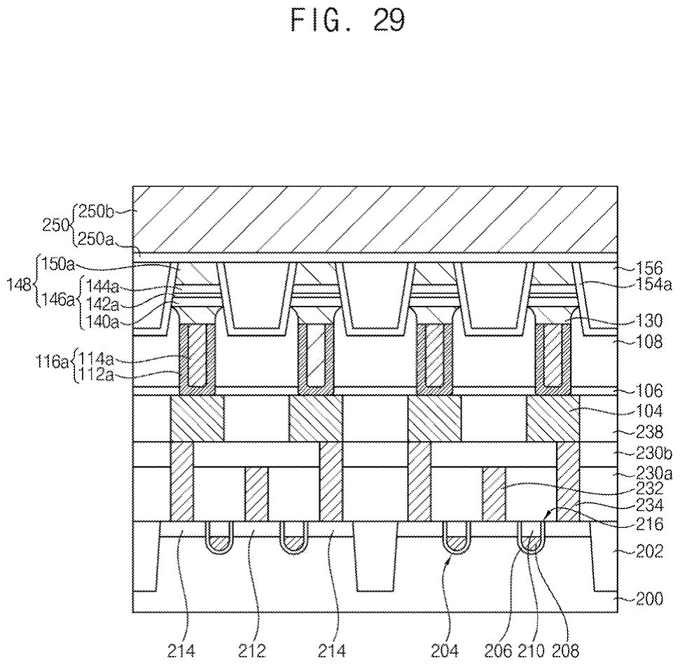

Referring to FIG. 29, the second insulating interlayer 156 and the protective layer 154 may be etched to form a trench exposing upper surfaces of the upper electrodes 150a. A bit line 250 may be formed in the trench.

In the process for forming the trench, the protective layer 154 on the upper electrode 150a may be also etched to form a protective layer pattern 154a. The trench may extend in a second direction perpendicular to the first direction.

In an implementation, a barrier metal layer may be formed on a sidewall and a bottom surface of the trench, and a metal layer may be formed on the barrier metal layer to fill the trench. The metal layer and the barrier metal layer may be planarized to form the bit line in the trench. The barrier metal layer may include, e.g., titanium, titanium nitride, tantalum, tantalum nitride, or the like. The metal layer may include, e.g., copper, tungsten, aluminum, or the like. In an implementation, the bit line 250 may include a barrier metal pattern 250a and a metal pattern 250b. The bit line 250 may contact the upper electrodes 150a.

In an implementation, a via contact may be further formed between the upper electrode 150a and the bit line 250.

Thereafter, a third insulating interlayer may be further formed to cover the second insulating interlayer and the bit line 250.

The magnetoresistive memory devices according to example embodiments may be used as a memory included in electronic products, e.g., mobile devices, memory cards, computers, or the like.

By way of summation and review, in a patterning process, defects due to re-deposition of metals included in the cell structure or defects due to a misalignment of an etching position could occur.

One or more embodiments may provide a magnetoresistive memory device having excellent characteristics.

In the magnetoresistive memory device according to example embodiments, an electrical short and leakage currents due to re-deposition of metals included in the cell structure may be decreased. Also, electrical defects due to a misalignment of the cell structure may be decreased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A magnetoresistive random access memory device, comprising:
a substrate;
conductive patterns on the substrate;
an insulating interlayer covering the conductive patterns;
a lower electrode contact passing through the insulating interlayer, the lower electrode contact contacting the conductive patterns;
a lower electrode on the lower electrode contact, the lower electrode including a rounded sidewall; and
a memory structure on the lower electrode, the memory structure including a stacked MTJ structure and upper electrode,
wherein:
a width of the lower electrode increases from a lower portion to an upper portion,
the memory structure has a sidewall slope such that a width of the memory structure increases from an upper portion to a lower portion, and
at least a portion of a sidewall of the lower electrode is covered by the first insulating interlayer.

2. The magnetoresistive random access memory device as claimed in claim 1, wherein an uppermost surface of the first insulating interlayer and an upper surface of the lower electrode are coplanar with each other.

3. The magnetoresistive random access memory device as claimed in claim 1, wherein:
an upper surface of the lower electrode and a lower surface of the MTJ structure have the same area, and
the upper surface of the lower electrode and the lower surface of the MTJ structure are aligned to each other.

4. The magnetoresistive random access memory device as claimed in claim 1, wherein:
the first insulating interlayer between the memory structures has a recessed shape, and
an upper surface of the first insulating interlayer between the memory structures is lower than an upper surface of the lower electrode.

5. The magnetoresistive random access memory device as claimed in claim 1, further comprising a protective layer covering an upper surface of the first insulating interlayer and a surface of the memory structure.

6. The magnetoresistive random access memory device as claimed in claim 1, wherein the protective layer contacts a portion of the sidewall of the lower electrode, or does not contact the sidewall of the lower electrode.

7. The magnetoresistive random access memory device as claimed in claim 1, wherein the lower electrode includes tungsten, titanium, tantalum, tungsten nitride, titanium nitride, or tantalum nitride.

8. The magnetoresistive random access memory device as claimed in claim 1, further comprising an insulation spacer on the sidewall of the lower electrode.

9. The magnetoresistive random access memory device as claimed in claim 1, wherein a bottom surface of the lower electrode has an area the same as or less than an area of an upper surface of the lower electrode contact.

10. The magnetoresistive random access memory device as claimed in claim 1, wherein:
the lower electrode includes a first portion and a second portion on the first portion,
the first portion of the lower electrode has a lower sidewall profile having a rounded sidewall profile such that a width of the first portion increases from a lower portion toward an upper portion, and
the second portion has an upper sidewall profile such that a width of the second portion decreases from a lower portion toward an upper portion.

11. A magnetoresistive random access memory device, comprising:
a substrate;
a lower electrode contact on the substrate;
a lower electrode contacting an upper surface of the lower electrode contact; and
a memory structure contacting an entire upper surface of the lower electrode, the memory structure including a stacked MTJ structure and upper electrode,
wherein the lower electrode has a rounded sidewall and a width of the lower electrode increases from a lower portion to an upper portion.

12. The magnetoresistive random access memory device as claimed in claim 11, further comprising a first insulating interlayer on the substrate, the lower electrode contact passing through the first insulating interlayer.

13. The magnetoresistive random access memory device as claimed in claim 12, wherein a bottom surface of the lower electrode is lower than an uppermost surface of the first insulating interlayer.

14. The magnetoresistive random access memory device as claimed in claim 12, further comprising a protective layer covering an upper surface of the first insulating interlayer and a surface of the memory structure.

15. The magnetoresistive random access memory device as claimed in claim 11, wherein:
the memory structure has a sidewall profile such that a width of the memory structure increases from an upper portion to a lower portion, and
a sidewall of the memory structure has a constant slope.

16. The magnetoresistive random access memory device as claimed in claim 11, wherein:
an upper surface of the lower electrode and a lower surface of the MTJ structure have the same area, and
the upper surface of the lower electrode and the lower surface of the MTJ structure are aligned to each other.

17. The magnetoresistive random access memory device as claimed in claim 11, wherein:
the lower electrode includes a first portion and a second portion on the first portion,
the first portion of the lower electrode has a lower sidewall profile having a rounded sidewall profile such that a width of the first portion increases from a lower portion toward an upper portion, and
the second portion has an upper sidewall profile such that a width of the second portion decreases from a lower portion toward an upper portion.

18. A magnetoresistive random access memory device, comprising:
a substrate;
a lower structure on the substrate;
an insulating interlayer covering the lower structure;
a lower electrode contact passing through the insulating interlayer and contacting a portion of the lower structure, the lower electrode contact having an upper surface lower than an uppermost surface of the insulating interlayer;
a lower electrode on the lower electrode contact, the lower electrode having a width increasing from a lower portion to an upper portion, and the lower electrode including a rounded sidewall; and
a memory structure in which an MTJ structure and an upper electrode are stacked on the lower electrode,
wherein a bottom surface of the lower electrode has an area that is the same as or less than an area of an upper surface of the lower electrode contact.

19. The magnetoresistive random access memory device as claimed in claim 18, further comprising an insulation spacer on a sidewall of the lower electrode.

20. The magnetoresistive random access memory device as claimed in claim 18, wherein:
the lower electrode contact includes a first electrode contact and a second electrode contact stacked on the first electrode contact,
the first electrode contact includes a first metal, and
the second electrode contact includes a second metal having a resistance lower than a resistance of the first metal.
